(19) United States
(12) Patent Application Publication
(10) Pub. No.: US 2016/0191833 A1
(43) Pub. Date: Jun. 30, 2016

(54) IMAGING ELEMENT, IMAGING DEVICE AND SEMICONDUCTOR DEVICE

(71) Applicant: KABUSHIKI KAISHA TOSHIBA, Tokyo (JP)

(72) Inventors: Yusuke HIGASHI, Kawasaki (JP); Takao Marukame, Tokyo (JP); Hiroki Noguchi, Yokohama (JP); Yuuichiro Mitani, Miurahayama (JP); Masumi Saitoh, Yokkaichi (JP)

(21) Appl. No.: 15/064,127

(22) Filed: Mar. 8, 2016

Related U.S. Application Data
(63) Continuation of application No. PCT/JP2014/074160, filed on Sep. 8, 2014.

(30) Foreign Application Priority Data
Sep. 10, 2013 (JP) 2013-187658

(51) Int. Cl. H04N 5/3745; H04N 5/376; H04N 5/378

(52) U.S. Cl. CPC H04N 5/37452; H04N 5/378; H04N 5/37455; H04N 5/3765

(57) ABSTRACT

An imaging element according to embodiments may comprise a plurality of photoreceivers (11a), a plurality of scanning circuits (11b), a first wiring (L2), a plurality of second wirings (L1), and at least one variable resistance element (VR2). The plurality of scanning circuits (11b) may be connected to the plurality of photoreceivers, respectively. Each of the second wirings (L1) may branch off from the first wiring and be connected to one of the scanning circuits. The at least one variable resistance element (VR2) may be located on the first wiring so as to electrically intervene between adjacent branching points (N1, N2) among a plurality of branching points between the first wiring and the second wirings.

### CROSS-REFERENCE TO RELATED APPLICATIONS

This application is a continuation of PCT international application Ser. No. PCT/JP2014/074160 filed on Sep. 8, 2014, which designates the United States and which claims the benefit of priority from Japanese Patent Application No. 2013-187658, filed on Sep. 10, 2013; the entire contents of which are incorporated herein by reference.

### FIELD

Embodiments described herein relate generally to an imaging element, an imaging device and a semiconductor device.

### BACKGROUND

Conventionally, in a field of image recognition, as fundamental processes, image processing such as a smoothing process of image, a subtraction process of images with different smoothness, an extraction (feature-point extraction) process of minimum value/maximum value after a subtraction process, a calculation process of feature amount in which gradient information about light value near feature point, or the like, is calculated, and so forth, is executed.

As a technique for executing these processes fast, there is a technology of silicon retina chip mimicking vital retinal nerves. In such technique, by connecting pixels formed on a semiconductor substrate via a variable resistance circuit constructed from MOSFETs (metal-oxide-semiconductor field-effect-transistor), a smoothing process between each pixel is executed fast. However, in the silicon retina chip, although it is possible to execute a smoothing process fast, there is a case where a pixel area for forming a variable resistance circuit in a pixel region of a semiconductor substrate increases, and thereby, the number of pixels decreases as compared with a conventional image sensor.

### BRIEF DESCRIPTION OF THE DRAWINGS

FIG. 1 is a schematic diagram showing an outline structure of an imaging device according to a first embodiment;

FIG. 2 is a circuit diagram showing an outline structure example of the imaging device according to the first embodiment;

FIG. 3 is a circuit diagram showing an outline structure example of the imaging device using a MOS transistor as a variable resistance element according to the first embodiment;

FIG. 4 is an illustration showing an example of a cross-section structure of a semiconductor device according to the first embodiment;

FIG. 5 is a first cross-section view showing a manufacturing process of the semiconductor device according to the first embodiment;

FIG. 6 is a second cross-section view showing the manufacturing process of the semiconductor device according to the first embodiment;

FIG. 7 is a third cross-section view showing the manufacturing process of the semiconductor device according to the first embodiment;

FIG. 8 is a fourth cross-section view showing the manufacturing process of the semiconductor device according to the first embodiment;

FIG. 9 is a fifth cross-section view showing the manufacturing process of the semiconductor device according to the first embodiment;

FIG. 10 is a circuit diagram showing an outline structure example of an imaging device according to a second embodiment;

FIG. 11 is an illustration showing an example of a cross-section structure of a semiconductor device according to the second embodiment;

FIG. 12 is a circuit diagram showing an outline structure example of an imaging device according to a third embodiment;

FIG. 13 is an illustration showing an example of a cross-section structure of a semiconductor device according to the third embodiment;

FIG. 14 is an illustration showing an example of a cross-section structure of a semiconductor device according to a fourth embodiment;

FIG. 15 is an illustration showing an example of a cross-section structure of a semiconductor device according to a fifth embodiment;

FIG. 16 is a circuit diagram showing an first example of a memory element according to the fifth embodiment;

FIG. 17 is a cross-section view showing a structure example of the memory element shown in FIG. 16;

FIG. 18 is a circuit diagram showing a second example of the memory element according to the fifth embodiment;

FIG. 19 is a cross-section view showing a structure example of the memory element shown in FIG. 18;

FIG. 20 is a circuit diagram showing an outline structure example of an imaging device according to a sixth embodiment;

FIG. 21 is a circuit block diagram showing a first example of an imaging device according to a seventh embodiment;

FIG. 22 is a circuit block diagram showing a second example of the imaging device according to the seventh embodiment;

FIG. 23 is a circuit block diagram showing a third example of the imaging device according to the seventh embodiment; and

FIG. 24 is a schematic diagram showing a structure example of a CMOS image sensor chip according to an eighth embodiment.

### DETAILED DESCRIPTION

Exemplary embodiments of an imaging element, an imaging device and a semiconductor device will be explained below in detail with reference to the accompanying drawings.

### First Embodiment

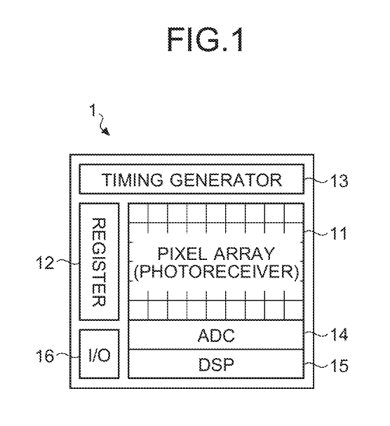

Firstly, an imaging element, an imaging device and a semiconductor device according to a first embodiment will be described in detail with the accompanying drawings. FIG. 1 is a schematic diagram showing an outline structure of an imaging device according to the first embodiment. As shown in FIG. 1, the imaging device 1 has a pixel array 11 being imaging elements, a register 12, a timing generator 13, an ADC (analog-to-digital converter) 14, a DSP (digital signal processor) 15 and an I/O (input/output) 16.

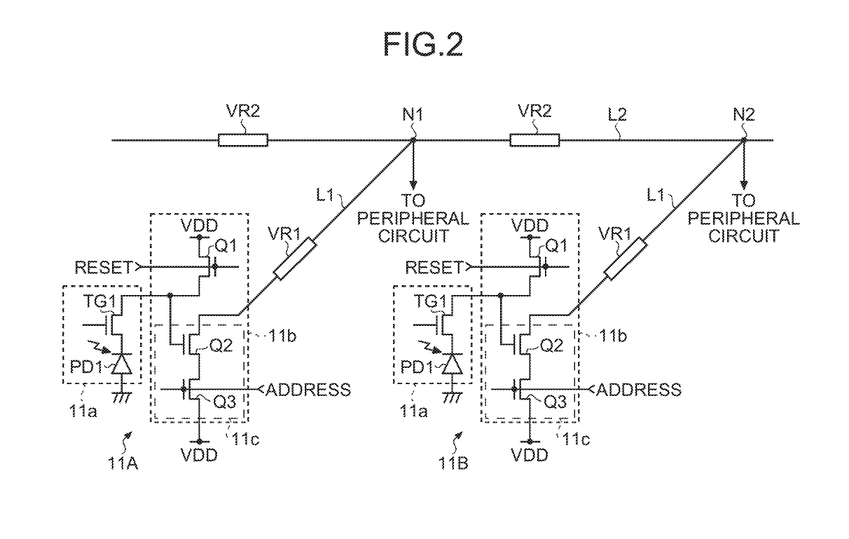

The pixel array 11 is imaging elements in which a plurality of pixels (hereinafter referred to as pixel cells) each of which includes a photoreceiver are arrayed in a matrix in a plane. FIG. 2 is a circuit diagram showing an outline structure example of the imaging elements according to the first embodiment. In FIG. 2, although a structure in which two pixel cells 11A and 11B are connected to one first wiring L2 is shown as an example, the pixel array 11 in FIG. 1 can have a structure in which a plurality of pixel cells are connected to a plurality of wirings, respectively.

As shown in FIG. 2, the pixel cell 11A has a photoreceiver 11a and a scanning circuit 11b. The photoreceiver 11a includes a photodiode PD1 and a transfer gate TG1. The scanning circuit 11b includes a reset transistor Q1 and an amplifier circuit 11c. The amplifier circuit 11c is a source follower circuit constructed from two MOSFETs (hereinafter referred to as MOS transistors) Q2 and Q3 of which sources are connected with each other. Regarding the two MOS transistors Q2 and Q3, the MOS transistor Q2 is an amplifier transistor configured to amplify an electric potential depending on charge stored in the photoreceiver 11a by a specific gain, and the MOS transistor Q3 is a switching transistor for selecting a read-out-target pixel cell. In the followings, the MOS transistor Q2 is referred to as an amplifier transistor Q2, and the MOS transistor Q3 is referred to as a switching transistor Q3.

A cathode of the photodiode PD1 in the photoreceiver 11a is connected to a gate of the amplifier transistor Q2 in the amplifier circuit 11c of the scanning circuit 11b via the transfer gate TG1. The photodiode PD1 converts incident lights into electrons. The transfer gate TG1 transfers electrons evolved in the photodiode PD1 to a charge storage region being referred to as a floating diffusion (ED). As a result, charge depending on an intensity of incident light is charged in the charge storage region.

To a gate of the amplifier transistor Q2, a power line VDD is also connected via the reset transistor Q1. To a gate of the reset transistor Q1, reset signal RESET for resetting charge in the charge storage region is applied. That is, the reset transistor Q1 has a rule of resetting an electric potential of the charge storage region before signal is read out from the photoreceiver 11a (pixel).

To a gate of the switching transistor Q3 in the amplifier circuit 11c, address signal ADDRESS for controlling readout of charge from the photoreceiver 11a is inputted. A source of the amplifier transistor Q2 in the amplifier circuit 11c is connected to a node N1 on the first wiring L2 via a second wiring L1 with a variable resistance element VR1. Therefore, a gate potential depending on charge stored in the charge storage region is appeared at the gate of the amplifier transistor Q2 via the transfer gate TG1. Because the amplifier circuit 11c is the source follower circuit 11c, the gate potential appeared at the gate of the amplifier transistor Q2 is converted into a source potential of the amplifier transistor Q2. As a result, the source potential of the amplifier transistor Q2 becomes an electric potential depending on an amount of light received by the photoreceiver PD1. The source potential is applied to the node N1 via the variable resistance element VR1 on the second wiring L1.

Such structure of the pixel cell 11A can be applied to the pixel cell 11B and the other pixel cells. Therefore, regarding the pixel cell 11B, a gate potential of the amplifier transistor Q2 depending on charge stored in the charge storage region is converted into a source potential via the transfer gate TG1, and the source potential is applied to the node N2 via the variable resistance element VR1 on the second wiring L1.

On the first wiring L2 between adjacent pixel cells (the pixel cells 11A and 11B, for instance) among the plurality of the pixel cells connected to the same first wiring L2, a variable resistance element VR2 is built. For example, between the nodes N1 and N2 where the adjacent pixel cells 11A and 11B are connected to the first wiring L2, respectively, the variable resistance element VR2 is built. Accordingly, a voltage value (light value) outputted to peripheral circuits from each of the nodes N1 and N2 is a value smoothed depending on a ratio R1/R2 of a resistance value R1 of the variable resistance element VR1 built on the second wiring L1 and a resistance value R2 of the variable resistance element VR2 built on the first wiring L2. Here, smoothing means rendering edges in an image smooth by softening differences of brightness values between adjacent pixels.

The greater the ratio R1/R2 is, the greater the smoothness, and the smaller the ratio R1/R2 is, the smaller the smoothness. For example, when the resistance value R2 is extremely greater than the resistance value R1, because a voltage value (light values) outputted from each of the nodes N1 and N2 is smoothed little, a substantively raw image data will be read out from the pixel array 11. On the other hand, when the resistance value R2 is smaller than the resistance value R1, a voltage value (light values) outputted from each of the nodes N1 and N2 is smoothed comparatively strongly, a dynamically smoothed image date will be read out from the pixel array 11. Thus, by varying the ratio R1/R2, it is possible to generate image data with different smoothness. Thereby, it is possible to smooth pixels and create a Gaussian pyramid constructed from a plurality of image information with difference smoothness while enlargement of the pixel area in the pixel array 11 is suppressed as much as possible. Furthermore, by executing a subtraction process of images with different smoothness, a feature-point extraction process and a feature-amount extraction process in peripheral circuits, it is possible to execute fundamental processes necessary for image recognition process fast. For example, by executing a subtraction process to two image data read out from the pixel array 11 as image data with different smoothness, it is possible to generate an edge image constructed from edges extracted from the image fast. The subtraction process of images with different smoothness, the feature-point extraction process and the feature-amount extraction process can be executed not only by peripheral circuits, but also by application software operating on a data processing device such as a CPU (central processing unit).

In FIG. 2, although the linearly adjacent pixel cells are connected with each other via the variable resistance element VR2, respectively, it is also possible that laterally-and-vertically adjacent pixel cells are connected with each other via the variable resistance elements VR2, respectively. When the variable resistance element VR2 is located between the linearly adjacent pixel cells, it is possible to read put linearly smoothed image data from the pixel array 11. On the other hand, when the variable resistance element VR2 is located between the laterally-and-vertically adjacent pixel cells, respectively, it is possible to read out two-dimensionally smoothed image data from the pixel array 11.

As the variable resistance elements VR1 and VR2, it is possible to use MOS transistors, for instance. However, it is not limited to the MOS transistors, it is also possible to use various kinds of resistance elements capable of varying a resistance value. For example, a resistance element with two terminals such as a ReRAM (resistance random access memory), a MRAM (magnetoresistive RAM), a PRAM (phase change RAM), an ion memory, an amorphous silicon memory, a polysilicon memory can be used as at least one of the variable resistance elements VR1 and VR2. Furthermore, instead of the variable resistance elements VR1 and VR2, it is also possible to build variable resistance circuits constructed from a plurality of transistors on the wiring layer 11L.

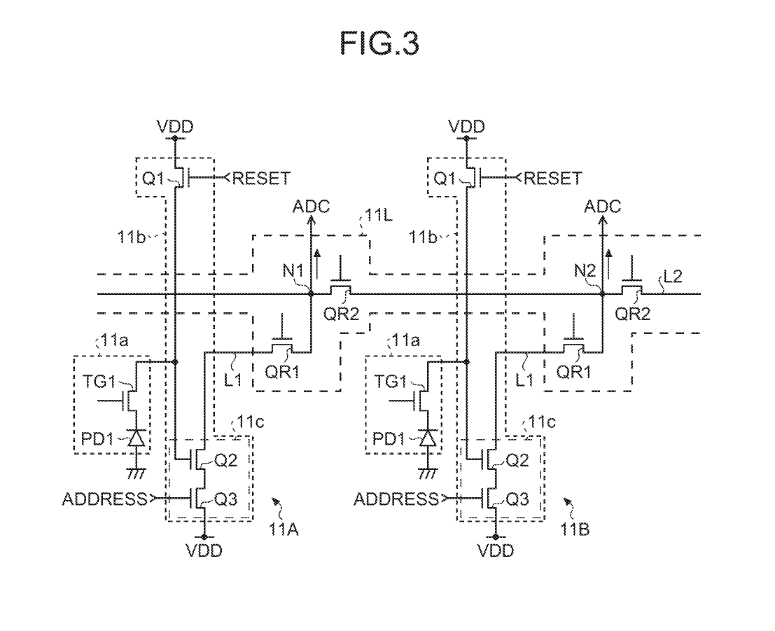

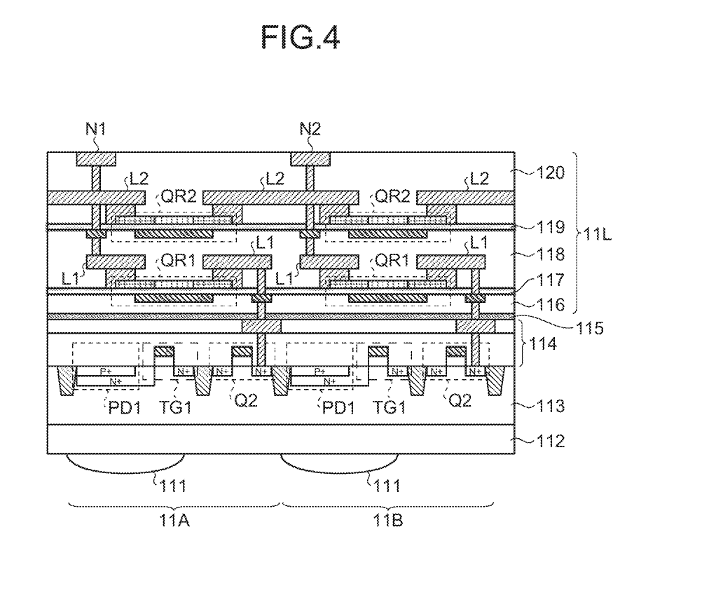

FIG. 3 is a circuit diagram showing an outline structure example of the imaging element in which MOS transistors are used for the variable resistance elements. As shown in FIG. 3, MOS transistors QR1 and QR2 used as the variable resistance elements VR1 an dVR2 are built on the wiring layer 11L connecting between adjacent pixels (the pixel cells 11A and 11B, for instance), respectively. FIG. 4 shows an example of a cross-section structure of a semiconductor device of the circuit structure shown in FIG. 3. In FIG. 4, for the sake of clarification, the reset transistor Q1 and the switching transistor Q3 in the amplifier circuit 11c are omitted. Furthermore, in FIG. 4, although a back-side-illumination semiconductor device is shown, the semiconductor device is not limited to such structure while it can be a top-side-illumination semiconductor device.

As the semiconductor device shown in FIG. 4, the pixel cell 11A includes a semiconductor substrate 113 having matrix-arrayed photodiodes PD1, transfer gates TG1 and amptransistors Q2 formed on a first face (upper face) of the semiconductor substrate 113. On a second face (back face) of the semiconductor substrate 113, a color filter 112 is joined. On a face in the color filter 112 opposite to the junction face with the semiconductor substrate 113, a micro lens 111 aligned to the photodiode PD1 is mounted. From the micro lens 111 to the photodiode PD1, light with a specific wavelength depending on the color filter 112 can be transmitted. For example, it is possible that a though hole is formed in the semiconductor device 113 between the micro lens 111 and the photodiode PD1, and it is also possible that a transparent substrate is used as the semiconductor substrate 113.

Over the upper face of the semiconductor substrate 113, a contact layer 114 is formed. In the contact layer 114, a via wiring for drawing out a source of the amplifier transistor Q2 electrically. On a top of the via hole, a pad for alignment with an upper layer is formed. On the contact layer 114, a diffusion preventing film 115 for preventing interlayer diffusion of atoms is formed.

On the diffusion preventing film 115, the wiring layer 11L including an interlayer insulators 116, 118 and a passivation 120 is formed. In particular, on the diffusion preventing film 115, the interlayer insulators 116 and 118 are formed. Between the interlayer insulators 116 and 118, a gate insulator 117 is formed, and across the gate insulator 117, the MOS transistor QR1 (see FIG. 3) is formed. In the diffusion preventing film 115, the interlayer insulator 116, the gate insulator 117 and the interlayer insulator 118, a via wiring and a wiring for electrically connecting a drain of the MOS transistor QR1 and the source of the amplifier transistor Q2 electrically drawn out to the top of the contact layer 114 are formed.

A source of the MOS transistor QR1 is electrically drawn out to a top of the interlayer insulator 118 through the via wiring formed in the interlayer insulator 118. On a top of the via hole, a pad for alignment with an upper layer is formed. On the interlayer insulator 118, a gate insulator 119 and the passivation 120 are formed.

The first wiring L2 in FIG. 2 is formed in the passivation 120, and the MOS transistor Q2 is formed across the gate insulator 119. The source of the MOS transistor QR1 drawn out to the top of the interlayer insulator 118 is electrically connected to the first wiring L2 through a via hole formed in the gate insulator 119 and the passivation 120 as a part of the first wiring L2. The node N21 of the first wiring L2 is electrically drawn out to a top of the passivation 120 through a via hole formed in the passivation 120. On the via hole, a pad for alignment for joining to another substrate (circuit substrate, for instance) may be formed.

A semiconductor layer used for the MOS transistors QR1 and QR2 may be an oxide semiconductor such as InGaZnO, ZnO, or the like, or may be Poly-Si, amorphous Si, SiGe, or the like. The semiconductor layer may be a film stack constructed from various kinds of films. As the film stack, for instance, InGaZno/Al₂O₃/InGaZnO/Al₂O₃, or the like, can be used. As the via wirings and the wiring layers formed in the interlayer insulators 116, 118 and the passivation 120, various kinds of conductors such as metals, doped semiconductors, or the like, can be used.

As described above, by forming the MOS transistors QR1 and QR2 at the wiring layer 11L formed on the semiconductor substrate 113 as the variable resistance elements VR1 and VR2, it is possible to execute the smoothing process of image date by analog without expansion of the pixel area.

The exampled cross-section structure shown in FIG. 4 is a just random example, and the structures of the MOS transistors QR1 and QR2 are not limited to such structure. For example, the MOS transistors QR1 and QR2 may have a double-gate structure in that gate electrodes are formed above and below a semiconductor layer. Also, the cross-section arrangement of each wiring is not limited to such arrangement shown in FIG. 4. For example, the wirings are arranged so that a direction of gate width of the MOS transistor QR1 located at the lower layer and a direction of gate width of the MOS transistor QR2 located at the upper layer is at right angles to each other. Furthermore, an arrangement of the transistors (including the photodiode PD1) formed on the semiconductor substrate 113, and so forth, is not limited to the arrangement shown in FIG. 4.

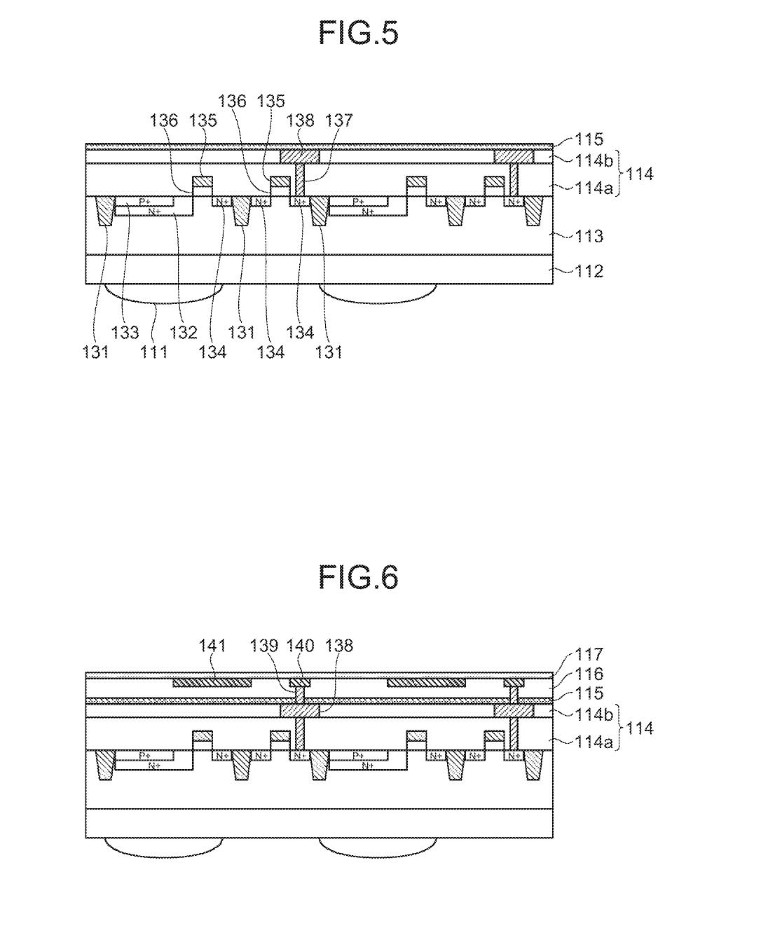

Next, a method of manufacturing the semiconductor device according to the first embodiment will be described in detail with accompanying drawings. FIGS. 5 to 9 are process cross-section diagrams showing a method of manufacturing the semiconductor device shown in FIG. 4, for instance. However, FIGS. 5 to 9 show a just random example of the method of manufacturing the semiconductor device shown in FIG. 4, and the method is not limited to these processes.

As shown in FIG. 5, as the conventional CMOS image sensor, an element separator layer 131 is formed on an upper surface of a semiconductor substrate 113. Then, by doping n-dopants and p-dopants in specific regions of the upper surface of the semiconductor substrate 113 by ion implantation using a mask or self-align, n-doped region 132 and p-doped region 133 are formed. Then, a contact layer 114a being an insulator is formed on the semiconductor substrate 113, and a via wiring 137 for electrically drawing out a source of a MOS transistor Q2 is formed in the contact layer 114a. Then, a pad 138 is formed on the contact layer 114a with the via wiring 137, a contact layer 114b is formed on the contact layer 114a with the pad 138, and then, an upper face of the pad 138 is exposed by the CMP (chemical mechanical polishing), for instance. After that, a diffusion preventing film 115 is formed on the planarized contact layer 114b.

Then, as shown in FIG. 6, an interlayer insulator 116 is formed on the diffusion preventing film 115, and a via wiring 139 for electrically drawing out the pad 138 is formed in the interlayer insulator 116. Then, a gate 141 of a MOS transistor QR1 is formed while a pad 140 is formed on the via wiring 139. Here, for the pad 140 and the gate 141, a metal such as copper (Cu) may be used, for instance. Then, a gate insulator 117 is formed on the gate 141 using the plasma CVD (chemical vapor deposition), or the like.

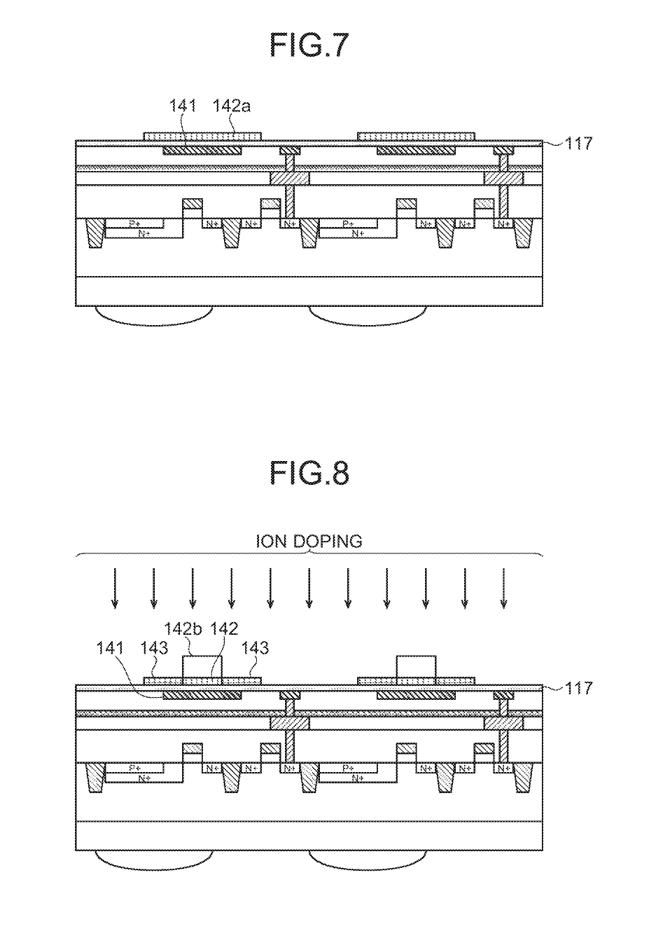

Then, as shown in FIG. 7, a semiconductor layer 142a is formed on the gate insulator 117, and the gate insulator 142a is selectively removed by etching. At this time, when the semiconductor layer 142a is an oxide semiconductor such as InGaZnO, or the like, the semiconductor layer 142a can be formed by sputtering. When the semiconductor layer 142a is polysilicon, amorphous silicon, or the like, the semiconductor layer 142a can be formed by the plasma CVD.

Then, as shown in FIG. 8, a mask pattern 142b is formed on the semiconductor layer 142a, and by doping dopants in the semiconductor layer 142a by ion implantation, a source 143 and a drain 143 are formed in the semiconductor layer 142a while a channel region 141 is formed in the semiconductor layer 142a. At this time, when the semiconductor 142a is an oxide semiconductor, by a method of forming an oxygen-depleted region using reducing plasma such as hydrogen plasma, or the like, or a method of introducing nitrogen using nitrogen-containing plasma such as ammonia, or the like, the source 143 and the drain 143 can be formed. When the semiconductor layer 142a is poly-Si, amorphous Si or SiGe, the source 143 and the drain 143 can be formed by implantation of impurities such as phosphorus, arsenic, boron, or the like.

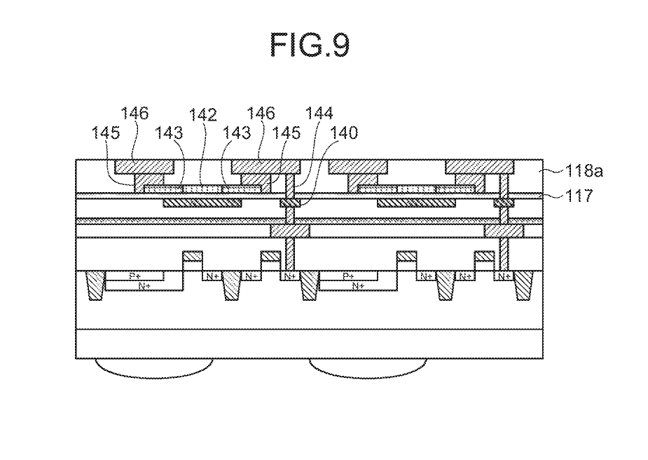

Then, as shown in FIG. 9, after the mask pattern 142b is removed, wirings 144 and 145 and a wiring layer 146 are formed so that they overlap the source 143, the drain 143 and the pad 140, respectively.

Then, by conducting the same processes as the processes shown in FIGS. 6 to 9, an upper MOS transistors QR2 are formed, and by connecting these MOS transistors QR2 by the wiring layer L2 such as a metal layer, the semiconductor device having the cross-section structure shown in FIG. 4 is manufactured.

As described above, because the first embodiment has the structure in that the adjacent pixels (the pixel calls 11A and 11B, for instance) are connected via the variable resistance element VR2, it is possible to execute the smoothing process of image date by analog without expansion of the pixel area.

Furthermore, in a case where a silicon retina chip is used, it is possible that a necessity of redesigning a pixel layout for the silicon retina chip may occur. On the other hand, because the first embodiment has the structure in that the variable resistance element VR2 is formed in the wiring layer 11L, it is possible to realize an imaging device having fundamental processing functions required for image recognition without substantively redesigning the pixel layout of the pixel array 11.

Because image processing such as a subtraction process of images with different smoothness, an extraction (feature-point extraction) process of minimum value/maximum value after the subtraction process, a calculation process of feature amount in which gradient information about light value near feature point, or the like, is calculated, and so forth, can be executed on peripheral circuits or external of the imaging element, detail explanations thereof are omitted here.

### Second Embodiment

Next, an imaging element, an imaging device and a semiconductor device according to a second embodiment will be described in detail with the accompanying drawings.

As described above, smoothness of image data read out from the pixel array 11 is decided based on the resistance ratio R1/R2 of the variable resistance elements R1 and R2. The resistance ratio R1/R2 can be adjusted by varying at least one of the resistance values R1 and R2. In other words, either one of the resistance values R1 and R2 can be defined as a fixed value. In the second embodiment, instead of the variable resistance element VR1 on the second wiring L1, an invariable resistance element of which resistance value cannot be varied is used. However, it is also possible to use an invariable resistance element instead of the variable resistance element VR2 on the first wiring L2.

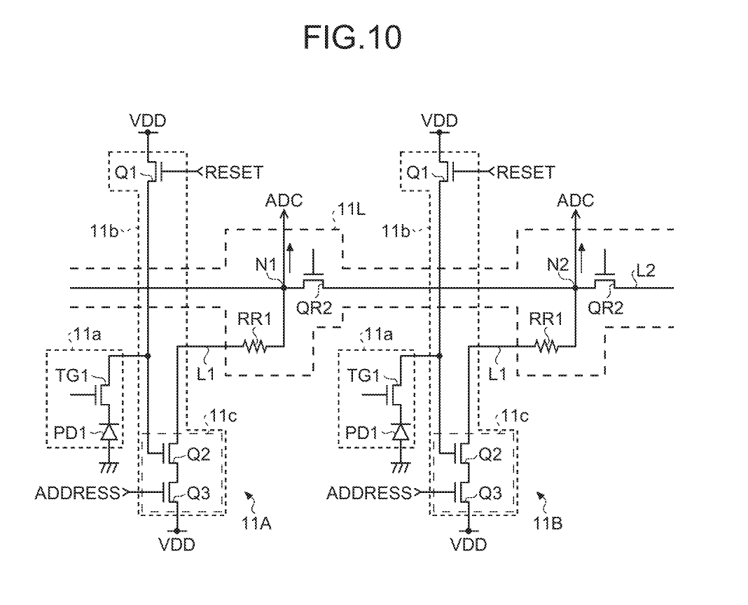

FIG. 10 is a circuit diagram showing an outline structure example of an imaging element according to the second embodiment. As evidenced by a comparison between FIG. 10 and FIG. 3, in the second embodiment, the MOS transistor QR1 on the second wiring L1 connected between the pixel cell 11A/11B and the first wiring L2 is replaced with an invariable resistance element RR1. The other structures can be the same as the imaging element shown in FIG. 3.

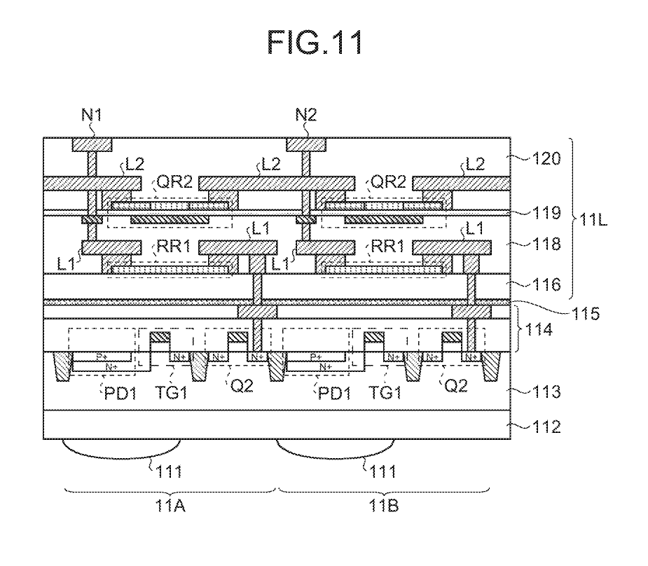

FIG. 11 shows an example of a cross-section structure of a semiconductor device of the circuit structure shown in FIG. 10. In FIG. 11 also, as with FIG. 4, the reset transistor Q1 and the switching transistor Q3 in the amplifier circuit 11c are omitted. Furthermore, in FIG. 11, although a back-side-illumination semiconductor device is shown, the semiconductor device is not limited to such structure while it can be a top-side-illumination semiconductor device.

As evidenced by a comparison between FIG. 11 and FIG. 4, in the second embodiment, the semiconductor device has the same structure as that of the first embodiment except for the lower gate insulator 117 in the wiring layer in is omitted, and an invariable resistance element RR1 is formed on the interlayer insulator 116 instead of the MOS transistor QR1. The invariable resistance element RR1 may be a semiconductor layer, for instance. The semiconductor layer may be an oxide semiconductor such as InGaZnO, or the like, or may be poly-Si, amorphous Si, SiGe, or the like. Furthermore, an oxygen-deplete region or a doped region may be formed in whole the semiconductor layer.

As described above, according to the second embodiment, as the above-described embodiment, it is possible to execute the smoothing process of image date by analog without expansion of the pixel area. Furthermore, in a case where a silicon retina chip is used, it is also possible to realize the imaging device having fundamental processing functions required for image recognition without substantive redesign of the pixel layout of the pixel array 11.

Moreover, in the second embodiment, because the invariable resistance element with a simple structure is used instead of one of the variable resistance elements VR1 and VR2, it is possible to reduce the number of manufacturing processes.

Because the other structures, manufacturing method and effects of the imaging element, the imaging device and the semiconductor device are the same as those of the above-described embodiment, detailed explanations thereof are omitted here.

### Third Embodiment

Next, an imaging element, an imaging device and a semiconductor device according to a third embodiment will be described in detail with the accompanying drawings.

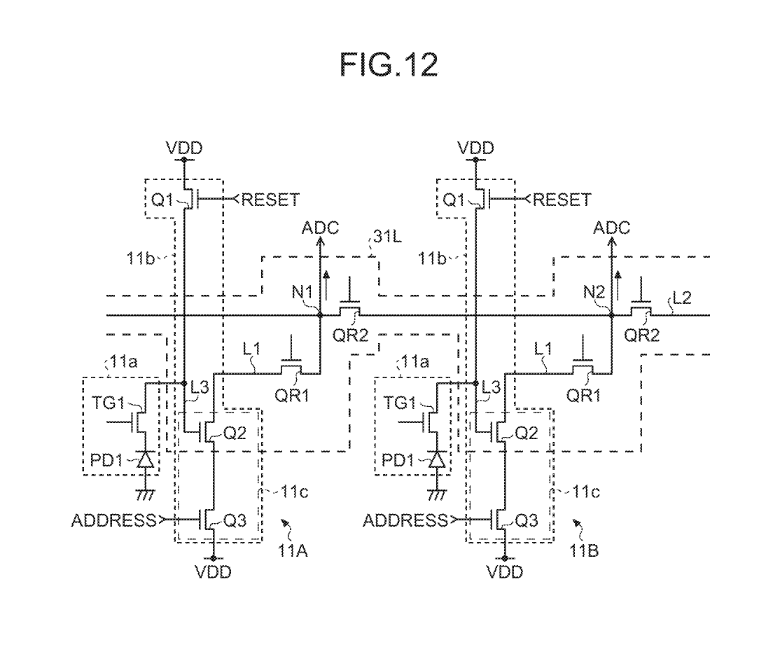

FIG. 12 is a circuit diagram showing an outline structure example of an imaging element according to the third embodiment. As evidenced by a comparison between FIG. 12 and FIG. 3, the third embodiment has the same circuit structure as the first embodiment. However, in the third embodiment, the amplifier transistor Q2 in the amplifier circuit 11c is built in a wiring layer 31L corresponding to the wiring layer 11L.

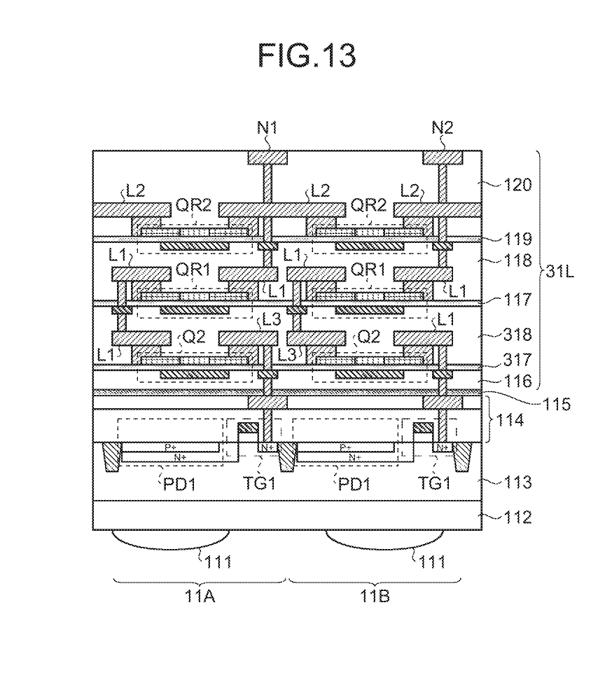

FIG. 13 shows an example of a cross-section structure of a semiconductor device of the circuit structure shown in FIG. 12. In FIG. 13 also, as with FIG. 4, the reset transistor Q1 and the switching transistor Q3 in the amplifier circuit 11c are omitted. Furthermore, in FIG. 13, although a back-side-illumination semiconductor device is shown, the semiconductor device is not limited to such structure while it can be a top-side-illumination semiconductor device.

As evidenced by a comparison between FIG. 13 and FIG. 4, in the third embodiment, an gate insulator 317 and an interlayer insulator 318 are formed between the interlayer insulator 116 and the gate insulator 117, and the amplifier transistor Q2 is formed across the gate insulator 317. In the contact layer 114, the diffusion preventing film 115, the interlayer insulator 116, the gate insulator 317 and the interlayer insulator 318, a connection wiring L3 connecting the transfer gate TG1 and the amplifier transistor Q2 is formed. The other structure may be the same as the semiconductor device shown in FIG. 4.

As described above, according to the third embodiment, as the above-described embodiments, it is possible to execute the smoothing process of image date by analog without expansion of the pixel area. Furthermore, in a case where a silicon retina chip is used, it is also possible to realize the imaging device having fundamental processing functions required for image recognition without substantive redesign of the pixel layout of the pixel array 11.

Moreover, in the third embodiment, because the amplifier transistor Q2 is formed in the wiring layer L3, it is possible to downsize the pixel area. Or, it is possible to expand a photo-acceptance area of the photodiode PD1 while maintaining the pixel area, and thereby, it is possible to improve a pixel sensitivity, a saturation electron number, and so forth.

Because the other structures, manufacturing method and effects of the imaging element, the imaging device and the semiconductor device are the same as those of the above-described embodiments, detailed explanations thereof are omitted here.

### Fourth Embodiment

Next, an imaging element, an imaging device and a semiconductor device according to a fourth embodiment will be described in detail with the accompanying drawings.

In the above-described embodiment, although the MOS transistors Q2 and Q3 are used as the variable resistance elements VR1 and VR2, it is not limited to such structure. For example, as the variable resistance elements VR1 and VR2, a ReRAM, a PRAM, a MRAM, amorphous Si, poly-Si, or a stack structure of these materials and metals can be used.

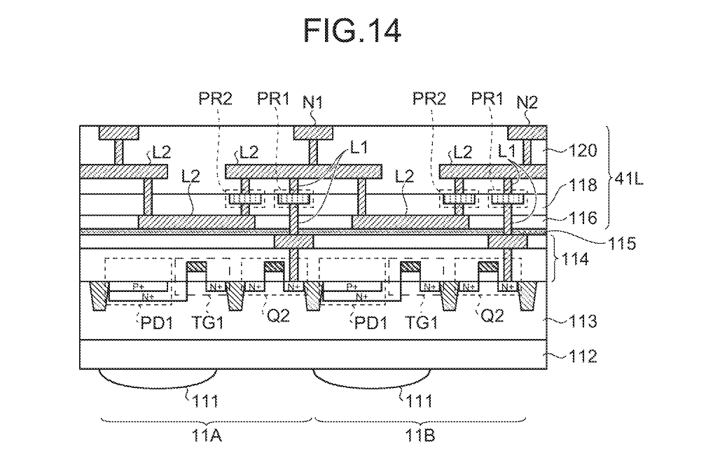

FIG. 14 shows an example of a cross-section structure of a semiconductor device of a circuit structure of an imaging element according to the fourth embodiment. In FIG. 14 also, as with FIG. 4, the reset transistor Q1 and the switching transistor Q3 in the amplifier circuit 11c are omitted. Furthermore, in FIG. 14, although a back-side-illumination semiconductor device is shown, the semiconductor device is not limited to such structure while it can be a top-side-illumination semiconductor device.

As evidenced by a comparison between FIG. 14 and FIG. 4, in the fourth embodiment, the gate insulators 117 and 119 in a wiring layer 41L corresponding to the wiring layer 11L are omitted, and the variable resistance elements VR1 and VR2 are formed in the interlayer insulator 118.

As described above, according to the fourth embodiment, as the above-described embodiments, it is possible to execute the smoothing process of image date by analog without expansion of the pixel area. Furthermore, in a case where a silicon retina chip is used, it is also possible to realize the imaging device having fundamental processing functions required for image recognition without substantive redesign of the pixel layout of the pixel array 11.

Because the other structures, manufacturing method and effects of the imaging element, the imaging device and the semiconductor device are the same as those of the above-described embodiments, detailed explanations thereof are omitted here.

### Fifth Embodiment

Next, an imaging element, an imaging device and a semiconductor device according to a fifth embodiment will be described in detail with the accompanying drawings.

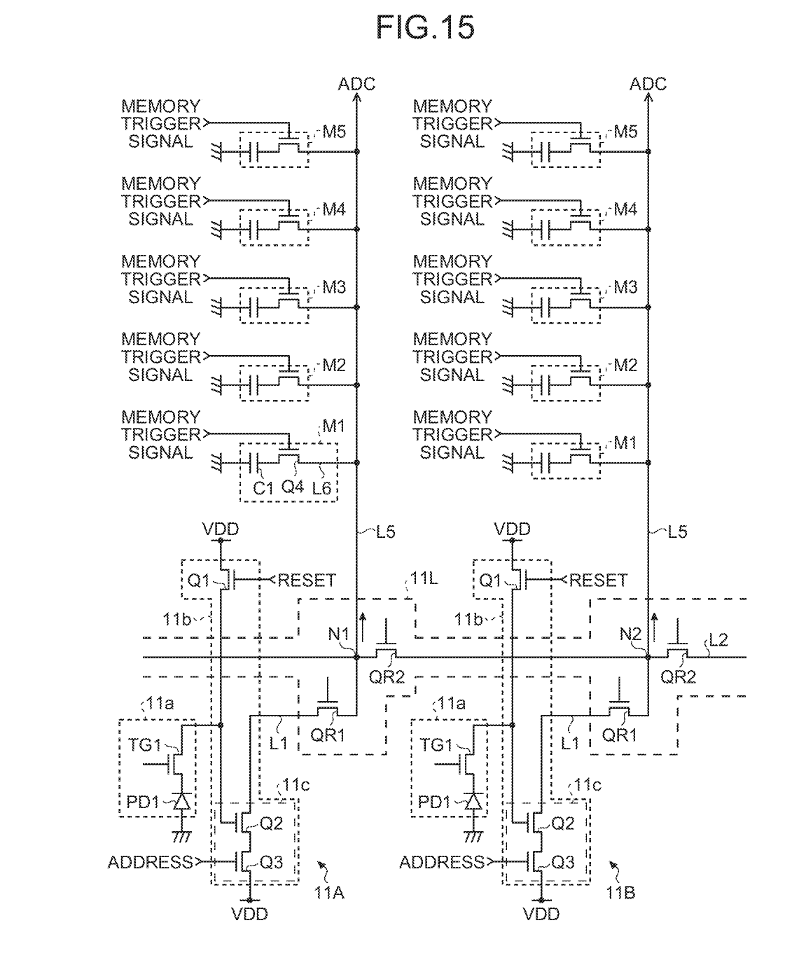

FIG. 15 is a circuit diagram showing an outline structure example of an imaging device according to the fifth embodiment. As evidenced by a comparison between FIG. 12 and FIG. 3, the pixel cells 11A and 11B according to the fifth embodiment have the same circuit structure as those of the first embodiment. However, in the fifth embodiment, one or more (five in FIG. 15) memory elements M1 to M5 are connected to a first wiring L5 connected to each node N1 and N2 via second wirings L6, respectively. The structure of each pixel cell is not limited to the circuit structure shown in FIG. 3 according to the first embodiment, and the circuit structure according to the other embodiments can be applied to the fifth embodiment.

To each memory element M1 to M5 connected to a certain node, which is assumed as the node N1, pixel information (i.e., pixel value) read out from the pixel cell 11A which is smoothed by different resistance ratio R1/R2 is stored as analog data. For example, the memory element M1 stores pixel information smoothed by lowest smoothness, the memory element M2 stores pixel information smoothed by smoothness higher than that of the pixel information stored in the memory element M1, the memory element M3 stores pixel information smoothed by smoothness higher than that of the pixel information stored in the memory element M2, the memory element M4 stores pixel information smoothed by smoothness higher than that of the pixel information stored in the memory element M3, and the memory element M5 stores pixel information smoothed by highest smoothness. Therefore, by reading out pixel information from the memory elements M1 to M5 connected to each node in order from the memory element M1, it is possible to read out image data smoothed by different smoothness. A correspondence relation between smoothness and the memory elements M1 to M5 is not limited to above-exampled manner.

Each memory element M1 to M5 has a structure in that a MOS transistor Q4 and a capacitor C1 is connected in series, for instance. However, it is not limited to such structure, it is also possible to use a variable resistance memory such as a ReRAM, a SOMOS (silicon/oxide/nitride/oxide/silicon) memory, or the like.

Next, an operation of the imaging element according to the fifth embodiment will be described. Charge depending on a light value of incident light at a certain time t is transferred from the photodiode PD1 to the charge storage region, and as a result, the source potential of the amplifier transistor Q2 becomes a value depending on the light value. At the time t, by setting as R1/R2<<1, pixel information with extremely lower smoothness (substantially without smoothing) is stored in a first stage memory element M1. Here, when it is assumed that a frame rate is about 30 to 60 FPS (frame per second) which may be a normal rate, each frame interval is equal to or greater than 10 milliseconds. Therefore, by changing the resistance values of the variable resistance elements VR1 and VR2 between frames, pixel information with different smoothness are stored in the memory elements M2 to M5, respectively, which are in the second stage and after that. Thereby, it is possible to obtain a plurality of pieces of pixel information with different smoothness in a short period of time. Here, to a gate of the MOS transistor Q4 in each of the memory elements M1 to M5, memory trigger signal for writing in the pixel information from the photodiode PD1 is inputted at a different timing depending on each write timing.

A pixel value under a state where the reset transistor Q1 is ON can be stored in one of the memory elements M1 to M5. In such case, by executing a subtraction process in which image data obtained under a reset state is used as a base, it is possible to filter low-frequency noise components in the image data.

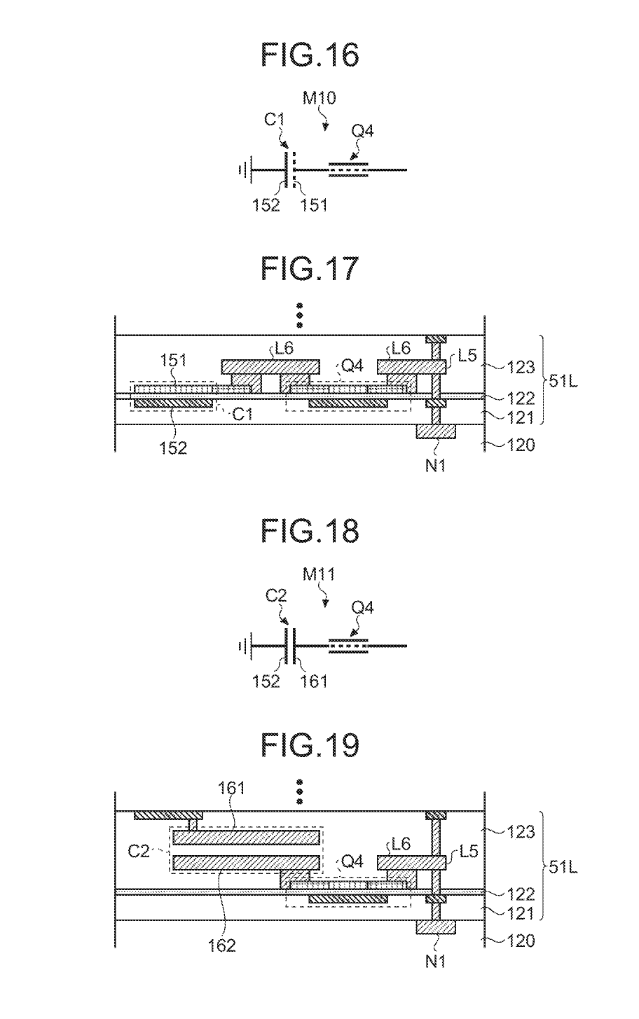

FIGS. 16 to 19 show specific examples of the memory elements M1 to M5 according to the fifth embodiment. FIG. 16 is a circuit diagram showing a first example of a memory element, and FIG. 17 is a structure example of the memory element shown in FIG. 16. FIG. 18 is a circuit diagram showing a second example of a memory element, and FIG. 19 is a structure example of the memory element shown in FIG. 18. The memory element M10 shown in FIGS. 16 to 19 may be common to the memory elements M1 to M5.

As shown in FIGS. 16 to 17, a structure of the MOS transistor Q4 in the memory element M10 according to the first example is the same as that of a wiring-layer transistor such as the above-described MOS transistors QR1 and QR2. One electrode 151 of the capacitor C1 may be formed by a semiconductor layer, and the other electrode 152 may be formed by a metal wiring. In a cross-section structure of the memory element M10 in each state, the interlayer insulator 121, the gate insulator 122 and the interlayer insulator 123 are stacked on the passivation 120 (or an interlayer insulator 123 described below) in this order, and the MOS transistor Q4 and the capacitor C1 are formed across the gate insulator 122. Therefore, when five-state memory elements M10 (the memory elements M1 to M5) are formed, a cross-section structure of the semiconductor device may be a structure in that a structure of a wiring layer 51L shown in FIG. 17 is repeated five times in a stack direction. In order to improve a retention characteristic of the memories, It is preferable that a transistor with a small off-leak current is applied to the MOS transistor Q4. For example, a MOS transistor in which InGaZnO is used as the semiconductor layer can be used as the MOS transistor Q4.

In the first example, although the semiconductor layer is used as the one electrode 151 of the capacitor C1, it is not limited to such structure. For example, as a memory element M11 according to the second example shown in FIGS. 18 and 19, both electrodes 161 and 162 of a capacitor C2 can be formed by a wiring layer, respectively. In such case also, when the five-state memory elements M10 (the memory elements M1 to M5) are formed, a cross-section structure of the semiconductor device may be a structure in that a structure of a wiring layer 51L shown in FIG. 19 is repeated five times in a stack direction.

Although the gate insulator 122 is used as a layer between the electrodes 151 and 152 of the capacitor C1 in the first example, and a part of the interlayer insulator 123 is used as a layer between the electrodes 161 and 162 of the capacitor C2 in the second example, it is not limited to such structures. For example, by a dielectric film, or the like, is used as a layer between the electrodes 151 and 152 or the electrodes 161 and 162, it is possible to adjust (increase or decrease) a capacitance of the capacitor C1 of C2.

As described above, according to the fifth embodiment, as the above-described embodiments, it is possible to execute the smoothing process of image date by analog without expansion of the pixel area. Furthermore, in a case where a silicon retina chip is used, it is also possible to realize the imaging device having fundamental processing functions required for image recognition without substantive redesign of the pixel layout of the pixel array 11.

Moreover, according to the fifth embodiment, because image date smoothed by different smoothness are stored in the memory elements formed in the wiring layer, it is possible to obtain a plurality of pieces of pixel information with different smoothness in a short period of time.

Because the other structures, manufacturing method and effects of the imaging element, the imaging device and the semiconductor device are the same as those of the above-described embodiments, detailed explanations thereof are omitted here.

### Sixth Embodiment

Next, an imaging element, an imaging device and a semiconductor device according to a sixth embodiment will be described in detail with the accompanying drawings.

In the fifth embodiment, the memory trigger signal for writing in the pixel information is inputted to a gate of the MOS transistor Q4 in each of the memory elements M1 to M5 at the different timing depending on each write timing. However, as described above, the frame rate deciding timings for writing in pixel information to the memory elements M1 to M5 are constant. Therefore, in the sixth embodiment, by delaying a single memory trigger signals in stages, a timing of writing to each memory element M1 to M5 is shifted.

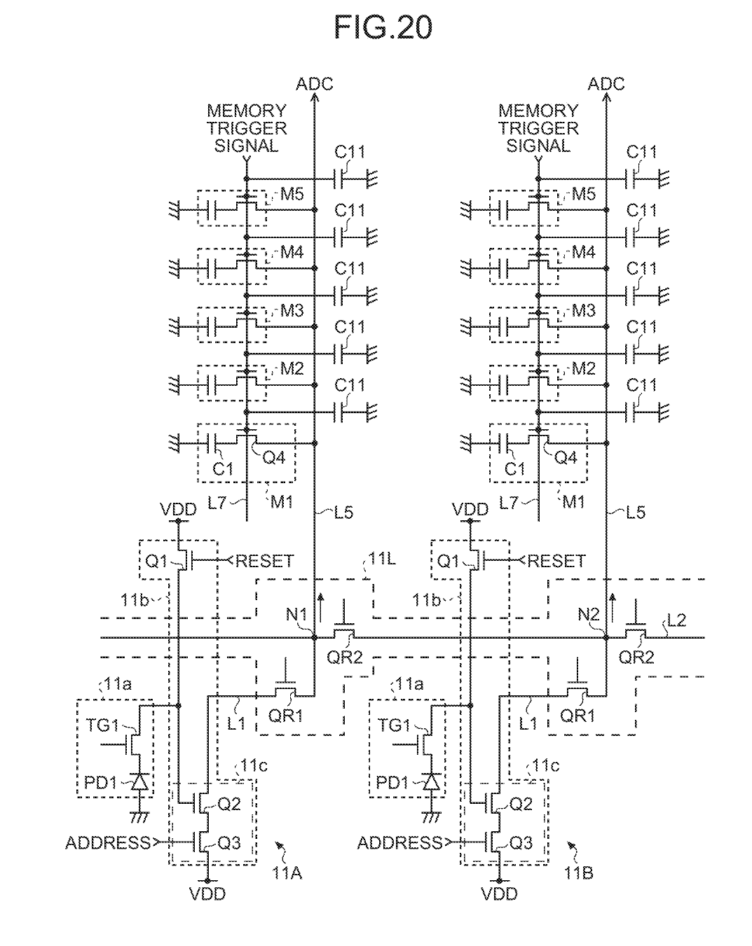

FIG. 20 is a circuit diagram showing an outline structure example of an imaging device according to the sixth embodiment. As evidenced by a comparison between FIG. 20 and FIG. 15, in the sixth embodiment, a common memory trigger signal is inputted to the gates of the MOS transistors Q4 in the memory elements M1 to M5. However, in a wiring L7 through which the memory trigger signal propagates, in front of the gate of the MOS transistor Q4 in each memory element M1 to M5, a delay capacitor C11 for delaying the memory trigger signal at each stage is connected. Thereby, because the memory trigger signal is delayed by a certain period of time at each stage, ON/OFF operations of the MOS transistor Q4 in the memory elements M1 to M5 are shifted by the certain period of time. Therefore, by controlling so that the resistance ratio R1/R2 is changed in synchrony with a delay interval, it is possible to store pieces of pixel information with different smoothness in the memory elements M1 to M5 by outputting memory trigger signal at once. Furthermore, as with a case of reading out pixel information, it is possible to read out pieces of pixel information with different smoothness stored in the memory elements M1 to M5 by outputting memory trigger signal at once.

Instead of the delay capacitors C11, buffers, or the like, can be used. However, normally, the delay capacitor C11 is preferable because it has an advantage in area.

As described above, according to the sixth embodiment, as the above-described embodiments, it is possible to execute the smoothing process of image date by analog without expansion of the pixel area. Furthermore, in a case where a silicon retina chip is used, it is also possible to realize the imaging device having fundamental processing functions required for image recognition without substantive redesign of the pixel layout of the pixel array 11.

Moreover, according to the sixth embodiment, as the fifth embodiment, it is possible to obtain a plurality of pieces of pixel information with different smoothness in a short period of time. Moreover, according to the sixth embodiment, it is possible to write/read out in/from the memory elements M1 to M5 by one-time output of memory trigger signal.

Because the other structures, manufacturing method and effects of the imaging element, the imaging device and the semiconductor device are the same as those of the above-described embodiments, detailed explanations thereof are omitted here.

### Seventh Embodiment

Next, an imaging device, an imaging device and a semiconductor device according to a seventh embodiment will be described in detail with the accompanying drawings.

### First Example

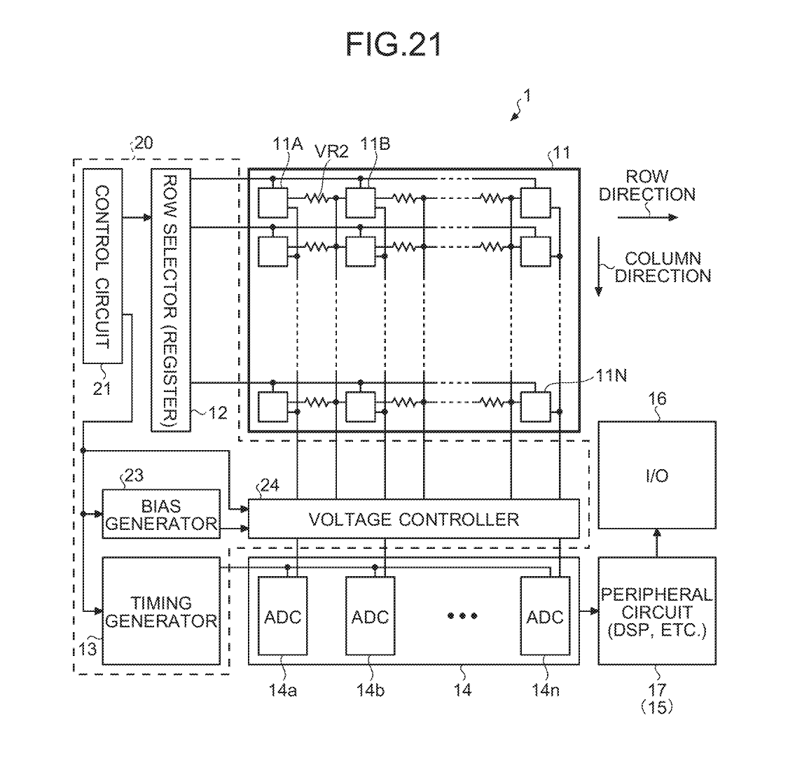

Firstly, a case where horizontally-arrayed pixel cells are connected with each other via variable resistance elements is explained as a first example. FIG. 21 is a circuit block diagram showing an outline structure of a CMOS image sensor being an imaging device according to the first example in the seventh embodiment. FIG. 21 is an illustration for showing a specific structure of the imaging device 1 shown in FIG. 1.

As shown in FIG. 21, the imaging device 1 according to the first example has the pixel array 11, the ADC 14, a peripheral circuit 17 including the DSP 15, the I/O 16 and a controller 20.

The pixel array 11 has a structure in which a plurality of pixel cells 11A to 11N are arrayed in a matrix in a plane. Each interval of the pixel cells 11A to 11N is connected via the variable resistance element VR2 arranged in the wiring layer 11L. In the example shown in FIG. 21, the variable resistance element VR2 is arranged between each interval of the pixel cells 11A to 11N arrayed in a row direction, respectively.

The controller 20 includes a row selector (the register) 12, the timing generator 13, a bias generator 23, a voltage controller 24 and a control circuit 21. The control circuit 21 controls the bias generator 23, a voltage controller 24, the row selector 12 and the timing generator 13. The row selector 12 controls readout of pixel signals from the plurality of the pixel cells 11A to 11N in a single horizontal line while selecting a row (horizontal line) of the pixel cells 11A to 11N being targets for readout. The voltage controller 24 controls gate voltages to be applied to the variable resistance elements VR2 for smoothing while controlling voltages of vertical output signal lines. However, the gate voltages for smoothing can be controlled by the row selector 12 or a dedicated voltage controller for the variable resistance elements VR2.

ADC 14 includes ADC blocks 14a to 14n for every vertical output signal lines. Each ADC block 14a to 14n converts a voltage value (pixel signal) read out from a corresponding vertical output signal line from analog to digital. The AD-converted pixel signal is digitally-processed by the DSP 15 in the peripheral circuit 17, for instance. A subtraction process of images with different smoothness, an extracting process of minimum value/maximum value, and so forth, may be executed by the DSP 15, for instance. The DSP 15 may execute a feature-amount extraction process of gradient information of pixel values around a feature point, or the like. Image signal processed by the peripheral circuit 17 is outputted from the I/O 16.

### Second Example

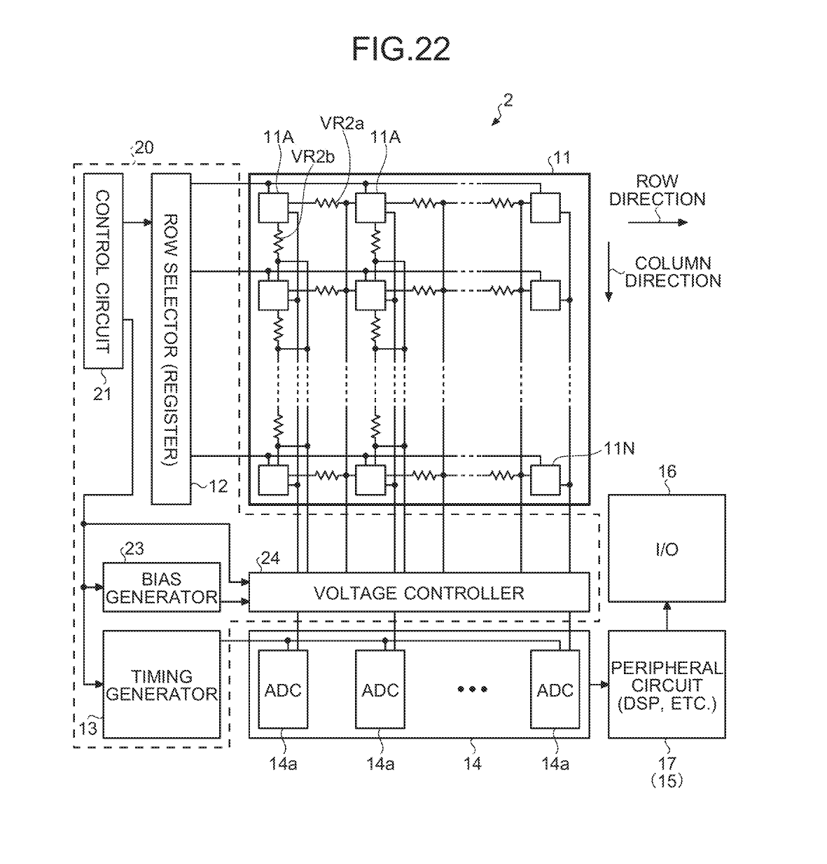

Next, a case where horizontally-and-vertically-arrayed pixel cells are connected with each other via variable resistance elements is explained as a second example. FIG. 22 is a circuit block diagram showing an outline structure of a CMOS image sensor being an imaging device according to the second example in the seventh embodiment. As shown in FIG. 22, the imaging device according to the second example has the same structure as the imaging device 1 shown in FIG. 21, and the horizontally-and-vertically-arrayed pixel cells are connected with each other via variable resistance elements VR2a or VR2b, respectively. Gate voltages to be applied to the variable resistance elements VR2a and VR2b for smoothing are controlled by the voltage controller 24. However, the gate voltages for smoothing can be controlled by the row selector 12 or dedicated voltage controllers for each of the variable resistance elements VR2a and VR2b.

### Third Example

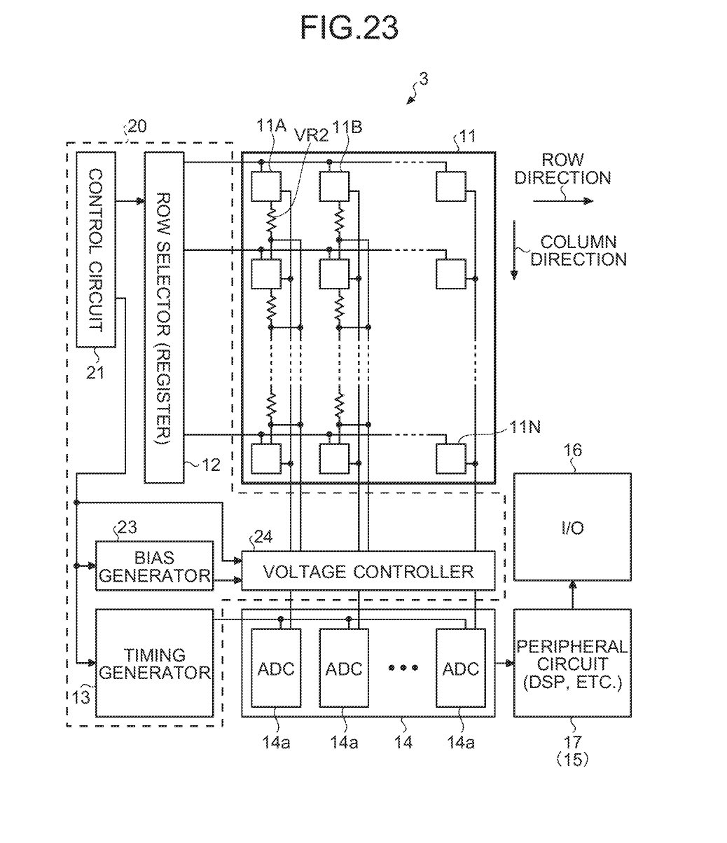

Next, a case where vertically-arrayed pixel cells are connected with each other via variable resistance elements is explained as a third example. FIG. 23 is a circuit block diagram showing an outline structure of a CMOS image sensor being an imaging device according to the third example in the seventh embodiment. As shown in FIG. 23, the imaging device according to the third example has the same structure as the imaging device 1 shown in FIG. 21, and the vertically-arrayed pixel cells are connected with each other via variable resistance elements VR2a or VR2b. Gate voltages to be applied to the variable resistance elements VR2 for smoothing are controlled by the voltage controller 24. However, the gate voltages for smoothing can be controlled by the row selector 12 or a dedicated voltage controller for the variable resistance elements VR2.

### Eight Embodiment

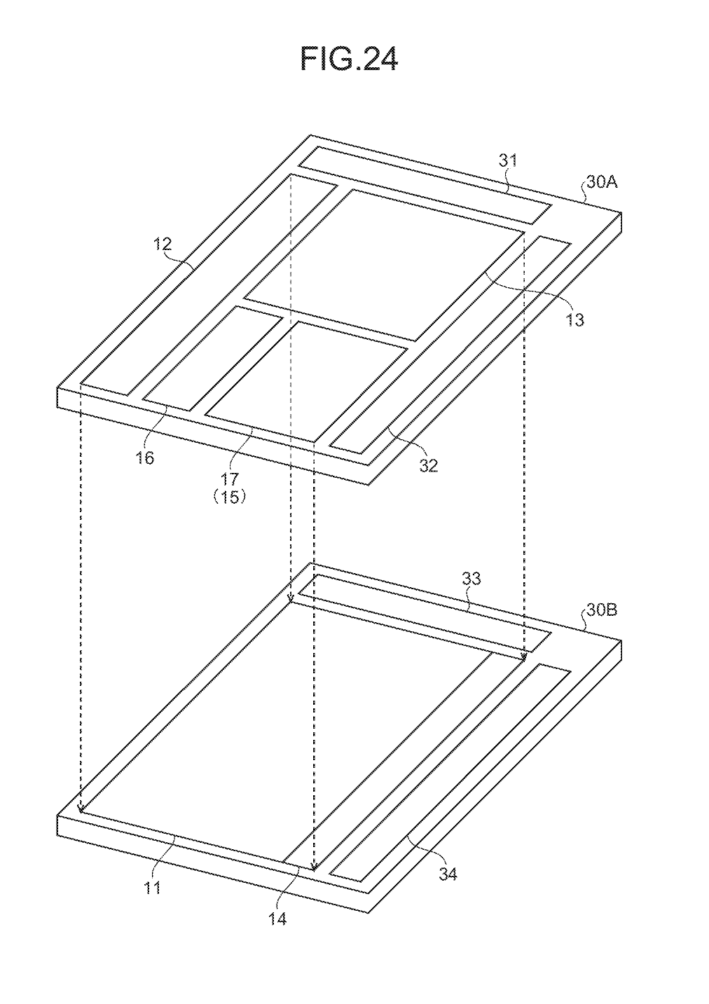

The structure of the CMOS image sensor exampled in the above-described embodiments can have a stack structure in which two chips 30A and 30B are jointed as shown in FIG. 24. In such case, by applying a stack structure constructed from TSVs (through silicon via) 31 to 34 and a layout in which the peripheral circuit 17 is placed over the pixel array 11, it is possible to expand an area of the peripheral circuit 17. As a result, it is possible to install a large-scale peripheral circuit 17, and thereby, it is possible to execute processes of extracting a feature point and a feature amount, or the like, fast.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imaging element comprising:
a plurality of photoreceivers;
a plurality of scanning circuits connected to the plurality of photoreceivers, respectively;
a first wiring;
a plurality of second wirings each of which branches off from the first wiring and is connected to one of the scanning circuits; and
at least one variable resistance element located on the first wiring so as to electrically intervene between adjacent branching points among a plurality of branching points between the first wiring and the second wirings.

2. The element according to claim 1, wherein the variable resistance element includes at least one of a transistor, a ReRAM, a MRAM, a PRAM, an ion memory, an amorphous silicon memory and a polysilicon memory.

3. The element according to claim 1, further comprising:
a substrate on which the plurality of the photoreceivers and at least a part of the plurality of the scanning circuits are located; and
one or more wiring layers located over the substrate and in which the first wiring and the second wirings are located,
wherein the at least one variable resistance element is located in the wiring layer.

4. The element according to claim 1, further comprising a plurality of variable resistance elements each of which located on each of the second wirings so as to electrically intervene between each of the scanning circuits and the first wiring.

5. The element according to claim 1, further comprising at least one memory elements each of which is connected to each of the plurality of the branching points and is configured to store pixel information of each of the photoreceivers.

6. The element according to claim 5, wherein each memory element includes a transistor and a capacitor connected with each other in series on a third wiring branching from a fourth wiring connected to each of the branching points.

7. The element according to claim 5, further comprising:
a substrate on which the plurality of the photoreceivers and at least a part of the plurality of the scanning circuits are located; and
one or more wiring layers located over the substrate and in which the first wiring and the second wirings are located,
wherein the at least one variable resistance element and the at least one memory element are located in the wiring layer.

8. The element according to claim 5, further comprising at least one delay element configured to delay trigger signal to be inputted into the at least one memory element.

9. An imaging device comprising:
the imaging element according to claim 1; and
a controller configured to control readout image signal from the imaging element while controlling a resistance value of the variable resistance element,
wherein the controller controls so that first image signal is read out from the imaging element while setting the resistance value of the variable resistance element as a first resistance value, and then second image signal is read out from the imaging element while setting the resistance value of the variable resistance element as a second resistance value different from the first resistance value.

10. The device according to claim 9, further comprising a peripheral circuit configured to execute at least one of a subtraction process of generating a difference between the first image signal and the second image signal, a feature-point extraction process of extracting a feature point of the first image signal based on the difference generated by the subtraction process, and a feature-amount calculation process of calculating a feature amount of the first image signal.

11. The device according to claim 9, wherein
the imaging element further including two or more memory elements each of which is connected to each of the plurality of the branching points and is configured to store pixel information of each of the plurality of the photoreceivers,
wherein the controller controls the imaging element so as to read out a difference between pixel information stored in the two or more memory elements connected to the same branching point in parallel.

12. The device according to claim 11, further comprising a peripheral circuit configured to execute at least one of a feature-point extraction process of extracting a feature point of the first image signal and a feature-amount calculation process of calculating a feature amount of the first image signal based on the difference between the pixel information read out from the imaging element.

13. An imaging device comprising:
a first substrate including
a pixel array including a plurality of pixel cells arrayed in a matrix in row and column directions and one or more variable resistance elements electrically-intervening between the pixel cells, and
a convertor configured to convert analog signal read out from the pixel cell into digital signal; and
a second substrate including
a selector configured to select a target pixel cell for readout in the pixel array,
a timing generator configured to control a readout timing from the pixel cell selected by the selector, and
a controller configured to control selection of the target pixel cell for readout by the selector and generation of the readout timing by the timing generator while controlling a resistance value of the variable resistance elements,
the second substrate is jointed with the first substrate in a direction perpendicular to the row direction and the column direction with respect to the array of the pixel cells.

14. A semiconductor device comprising:
a semiconductor substrate;
a plurality of photoreceivers arraying on an upper surface of the semiconductor substrate in a matrix in row and column directions being parallel to the upper surface;
a plurality of scanning circuit connected to the plurality of the photoreceivers, respectively;
a wiring layer located over the upper surface of the semiconductor substrate;
a first wiring located in the wiring layer;
a plurality of second wirings located in the wiring layer and each of which branches off from the first wiring and is connected to one of the plurality of the scanning circuits; and
at least one variable resistance element located in the wiring layer so as to electrically intervene between adjacent branching points among a plurality of branching points between the first wiring and the second wirings.
